(19) United States
(12) Patent Application Publication
(10) Pub. No.: US 2015/0221485 A1
(43) Pub. Date: Aug. 6, 2015

(54) TUBULAR TARGET

(71) Applicant: PLANSEE SE, Reutte (AT)

(72) Inventors: Walter Mutschlechner, Reutte (AT); André Dronhofer, Reutte (AT); Christian Linke, Ehenbichl (AT)

(73) Assignee: PLANSEE SE, Reutte (AT)

(21) Appl. No.: 14/428,837

(22) PCT Filed: Sep. 13, 2013
(86) PCT No.: PCT/AT2013/000152

§ 371 Date: Mar. 17, 2015

(30) Foreign Application Priority Data
Sep. 17, 2012 (AT) GM365/2012 17.

(51) Int. Cl. H01J 37/34

(52) U.S. Cl. CPC H01J 37/3423; H01J 2237/332

(57) ABSTRACT

A target for a cathode atomization system has a tubular target body made of an atomization material and two connection pieces, fastenable to the target body, for connecting the target body to a cathode atomization system. A first connection piece is connectable to a first end of the target body and a second connection piece is connectable to a second end of the target body. At least one locking device is formed on each connection piece, in order to connect the respective connection piece to the target body so that it is secured against rotation.

The invention relates to a target for a cathode atomization system having a tubular target body.

EP 1 225 249 B1 discloses a tubular target for cathode atomization systems. According to one configuration, a backing tube or a connection tube is arranged in each case at the ends of a tubular target body made of an atomization material. The target is installed into a system by means of the backing tubes, which protrude out of the target body. In one configuration, a backing tube is inserted into an open end of the target body and then secured by means of a screw, which is screwed into an end edge of the target body through a flange of the backing tube. Alternatively, an external thread is provided on the target body for a union nut, by means of which a flange of the backing tube can be pressed onto the end face of the target body.

It is an object of the invention to provide a tubular target which can be mounted easily and securely.

This object is achieved by the features of claim 1.

The dependent claims relate to advantageous configurations.

According to claim 1, provision is made of a target for a cathode atomization system, having a tubular target body made of an atomization material and two connection pieces fastenable to the target body. By means of the connection pieces, the target body can be connected or fastened to a cathode atomization system or sputtering system. A first connection piece is connectable to a first end of the target body and a second connection piece is connectable to a second end of the target body. A connection piece can be produced from or consist of one or more parts, such that a reliable vacuum-tight connection of the target body to a cathode atomization system is ensured.

Each connection piece has at least one locking means, in order to fasten or to lock the respective connection piece to the target body in a manner secured against rotation. That is to say, after the respective connection piece has been connected to the target body, rotation of the respective connection piece about a longitudinal axis of the tubular target body is blocked or disabled by means of the at least one locking means. In other words, the at least one locking means secures the respective connection piece against rotation relative to the target body. A locking means can be formed on a connection piece, for example, as a protruding lug or as a latching element, which engages or latches into corresponding cutouts on the target body when the connection piece assumes its final or operating position on the target body. In other words, at least one locking means is formed on each connection piece and during use—i.e. upon rotation of the target in a system—ensures that the torque transmitted to the connection pieces is reliably transmitted to the target body. Rotation or shifting of the connection pieces relative to the target body about the longitudinal axis of the tubular target body is prevented. In EP 1 225 249 B1, a connection tube is secured on the target body by means of a screw, by a flange or by means of a union nut. In contrast thereto, the invention provides a target in which the locking means is formed on the respective connection piece, in particular is formed in one piece with the connection piece. That is to say, the invention provides a target having fewer components, as a result of which a simpler and therefore time-saving mounting of the target becomes possible without thereby impairing the secure connection between the target body and the connection pieces.

The at least one locking means on the respective connection piece is preferably designed to engage into at least one recess on the circumference of the target body. By way of example, the at least one locking means is formed as one or more protrusions or as one or more (latching) lugs on the respective connection piece.

It is particularly preferable that the at least one locking means is formed as a flange with at least one recess, interruption or gap, such that the flange engages into a corresponding recess on the target body when the respective connection piece is being inserted or pushed in. By way of example, an end edge of the target body has an elevation, which engages into the corresponding recess on the flange. By way of example, at least 2, 3, 4 or 8 recesses are provided on the flange, in order to produce locking secured against rotation.

According to one configuration, the at least one locking means is formed as a latching element, which is designed to latch into a corresponding latching receptacle on the target body. By way of example, the locking means is formed as a spring pin or as a latching lug pretensioned with a spring, which spring pin or which latching lug latches into a corresponding receptacle or depression in the target body when the connection piece is inserted into the target body and reaches its final position.

The connection pieces are preferably connectable to the target body in a re-detachable manner That is to say, after the end of an operating life of the target, the connection pieces can be detached from the target body again, in order for example to be inserted into a new target body. By way of example, a bayonet closure is provided between the connection piece and the target body. That is to say, the at least one locking means is formed as a bayonet closure element. By way of example, corresponding protrusions or lugs are formed on a connection piece, and corresponding longitudinal and transverse grooves into which the lugs engage are formed on the target body. Alternatively, longitudinal and transverse grooves or longitudinal and transverse slots are provided on the connection piece, and corresponding protrusions or lugs formed on the target body engage thereinto. In this way, the connection pieces are connected to the target body in a re-detachable manner easily and reliably.

At least one securing element with a connecting axis perpendicular to the tubular target body axis is preferably provided for at least one connection piece. By way of example, provision is made of at least one screw, a rivet or a split pin, which is guided perpendicularly to the target body axis through the connection piece and the target body and connects the connection piece to the target body in a manner secured against rotation.

According to one configuration, at least one connection piece is integrally connected to the target body. By way of example, a connection piece is adhesively bonded or soldered to the target body, so as to establish an electrically conductive connection between the components. In particular, soldering or adhesive bonding makes the connection between the components more stable. After the end of the operating life of the target, the connection between the components can be detached in order to reuse the connection pieces. By way of example, heating of the target decomposes an adhesive or liquefies a solder, in order to detach the connection and to separate the connection pieces from the target body.

According to a preferred configuration, provision is made of a target for a cathode atomization system, having a tubular target body made of an atomization material and two connection pieces for connecting the target body to a cathode atomization system. A first connection piece is screwable to a first end of the target body and a second connection piece is screwable to a second end of the target body. By way of example, the connection pieces have an external thread and the target body has a corresponding internal thread, or the connection pieces have an internal thread and the target body has a corresponding external thread. In addition, the two connection pieces are integrally connected to the target body. By way of example, these are adhesively bonded, soldered or welded to one another. That is to say, the screw connection is additionally secured by the integral bond, in which case the connection as described above can be detached again by heating, in order to screw the connection pieces out of the target body for reuse.

According to one configuration, at least one connection piece has at least one depression on its outer circumference, into which solder material can be introduced for connecting the connection piece to the target body. By way of example, provision is made of at least one circumferential groove on the connection piece, into which solder platelets or a solder ring are placed before the components are put or screwed together, then the connection piece is inserted into the target body and the target is heated, such that the solder melts and the target body is connected to the connection piece. In this way, the components of the target can be connected to one another simply, quickly and reliably.

An electrically conductive material is preferably arranged between the connection pieces and the target body in order to ensure a reliable electrical connection of the components, for example a graphite foil or a copper mesh or, as described above, an electrically conductive adhesive or solder material.

According to one configuration, at least one connection piece has a conical outer face, which is designed to engage into a corresponding conical opening at one end of the target body. That is to say, a conical connection is formed between the connection piece and the target body, and this can be additionally secured against rotation by locking means as described above.

It is preferable that the connection pieces connected to the target body do not extend over the entire length of the tubular target body. That is to say, the connection pieces can be inserted into the respective ends of the target body, such that the outwardly pointing end of the connection pieces can be provided, for example, with further connection elements, for example protrusions or flanges, for connection to a cathode atomization system.

Embodiments of the invention will be explained in more detail with reference to the figures.

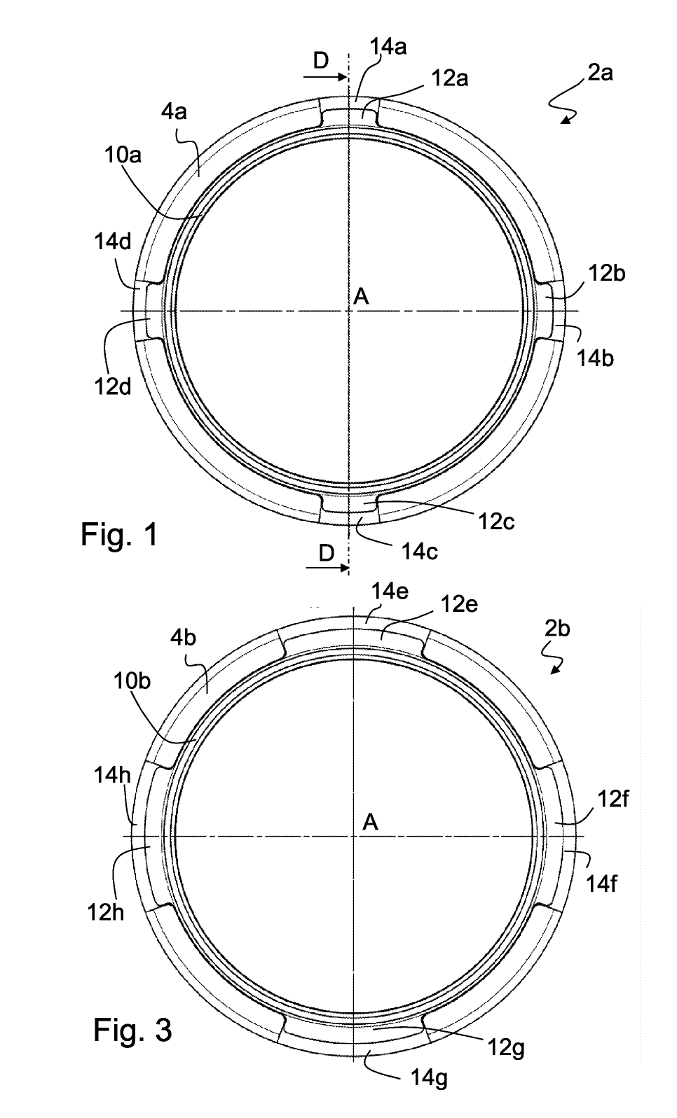

FIG. 1 shows an axial plan view of a tubular target according to a first configuration,

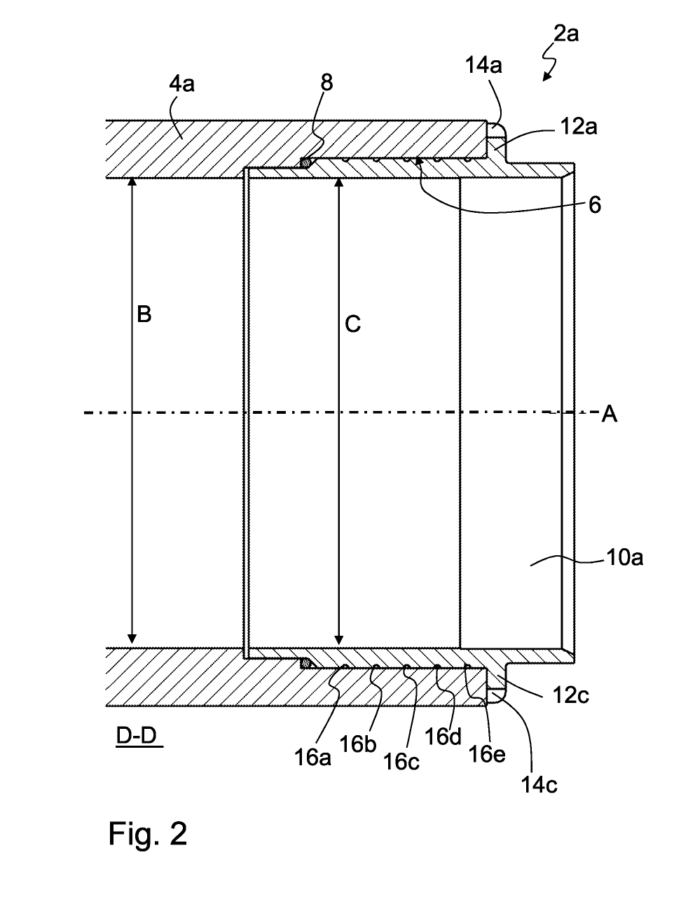

FIG. 2 shows a lateral sectional view of the target shown in FIG. 1, and

FIG. 3 shows an axial plan view of a tubular target according to a second configuration.

FIG. 1 shows a plan view in the direction of the longitudinal axis A of a tubular target 2a according to a first configuration. The target 2a is designed for use in cathode atomization systems and has a tubular target body 4a made of an atomization material. Both ends of the target 2a have the same or an identical configuration, and therefore for the sake of clarity only one end of the target 2a or of the target body 4a is shown in the figures. A tubular connection piece 10a is inserted in each case at the open ends of the target body 4a. The target 2a can be connected to a cathode atomization system by means of the connection pieces 10a. During use, the target 2a is installed in a vacuum chamber of a system, with cooling devices and a magnet apparatus, for example, being arranged in the internal volume of the hollow target 2a. The connection pieces 10a ensure a gastight connection between the target 2a and the system.

The target body 4a surrounds the connection pieces 10a concentrically, the connection pieces 10a protruding out of the target body 4a (FIG. 2) in order to connect the target 2a to a system. The connection pieces 10a are in each case pushed into an end of the target body 4a, such that a flange or other protruding elements for fastening to a system, for example, can be formed at the outer or exposed ends of the connection pieces 10a.

FIG. 2 shows a lateral sectional view of an end of the tubular target 2a shown in FIG. 1 along the line D-D. The connection piece 10a shown corresponds to the second connection piece (not shown) arranged at the other end of the target 2a. The connection piece 10a has flange elements 12a-d or protrusions in the radial direction, these being designed to engage into corresponding cutouts 14a-d or depressions on the end face of the target body 4a. The flange elements 12a-d and cutouts 14a-d secure the pushed-in connection piece 10a against rotation with respect to the target body 4a. In other words, the flange elements 12a-d lock the connection piece 10a on the target body 4a in a manner secured against rotation.

A plurality of circumferential grooves 16a-e are provided over the circumference of the connection piece 10a which is pushed into the target body 4a. Before insertion into the target body 4a, solder material is introduced into the grooves 16a-e, for example in the form of solder wire or solder platelets. After insertion, the target 2a or the end region of the target 2a is heated, such that the introduced solder material melts and a gastight, electrically conductive connection is established between the connection piece 10a and the target body 4a.

The target body 4a has a receiving opening, into which the connection piece 10a is pushed. An internal fold 6 on the target body serves as a depth stop for the pushed-in connection piece 10a. The internal diameter A of the target body 4a and the internal diameter C of the connection piece 10a are the same or substantially the same, and therefore a planar transition without a step is provided between the two components. A sealing ring 8 is arranged in the fold 6 and, in addition to the soldering described above, ensures a gastight connection between the connection piece 10a and the target body 4a. Alternatively, no sealing ring 8 is provided.

FIG. 3 shows a plan view of a target 2b according to a second configuration. Unless stated otherwise, the elements and functions of the target 2b correspond to the elements and functions described above with respect to the first configuration of the target 2a. In contrast to the first configuration, wider flange elements 12e-h are provided on the connection piece 10b and corresponding wider cutouts 14e-h are provided on the target body 4b. Wider flange elements 12e-h are, for example, more resilient to shearing stresses during operation or rotation of the target 2b in a cathode atomization system.

Alternatively, for example, provision can be made of only one flange element or of a multiplicity of flange elements, in order to establish a connection between the connection piece and the target body which is secured against rotation.

### LIST OF REFERENCE SIGNS

2a-b Tubular target
4a-b Target body
6 Fold
8 Sealing ring
10a-b Connection piece
12a-h Flange element
14a-h Cutout
16a-e Circumferential groove
A Target axis
B Target body internal diameter
C Connection piece internal diameter

1-11. (canceled)

12. A target for a cathode atomization system, comprising:
a tubular target body formed of an atomization material, said target body having a first end and a second end;
first and second connection pieces, connectable to said target body, for connecting said target body to the cathode atomization system, wherein said first connection piece is connectable to said first end of said target body and said second connection piece is connectable to said second end of said target body;
at least one locking device formed on each of said first and second connection pieces and configured to secure the respective said connection piece against rotation relative to said target body.

13. The target according to claim 12, wherein said at least one locking device is integrally formed in one piece with the respective said connection piece.

14. The target according to claim 12, wherein said at least one locking device is configured to engage into at least one recess formed in said target body.

15. The target according to claim 12, wherein said at least one locking device is a flange having at least one recess formed therein.

16. The target according to claim 12, wherein said at least one locking device comprises a latching element configured to latch into a corresponding latching receptacle formed on said target body.

17. The target according to claim 12, wherein said at least one locking device is a bayonet closure element.

18. The target according to claim 12, which comprises at least one securing element for at least one connection piece, said at least one securing element having a connecting axis perpendicular to a target body axis.

19. The target according to claim 18, wherein said at least one securing element is selected from the group consisting of a screw, a rivet, and a split pin.

20. The target according to claim 12, wherein at least one of said connection pieces is integrally connected to said target body.

21. The target according to claim 20, wherein said at least one connection piece is adhesively bonded or soldered to said target body.

22. The target according to claim 12, wherein at least one of said connection pieces is formed with at least one depression on an outer circumference thereof, for receiving solder material forming a connection between said connection piece to said target body.

23. The target according to claim 22, wherein said at least one depression is a circumferential groove.

24. The target according to claim 12, which comprises an electrically conductive material arranged between said connection pieces and said target body.

25. The target according to claim 24, wherein said electrically conductive material is selected from the group consisting of electrically conductive adhesive, solder, graphite foil and a copper mesh.

26. The target according to claim 12, wherein at least one of said connection pieces has a conical outer face configured to engage into a corresponding conical opening at one end of said target body.
